(19) United States
(12) Patent Application Publication
(10) Pub. No.: US 2017/0267903 A1
(43) Pub. Date: Sep. 21, 2017

(54) Urethane Adhesive for Laminated Sheets

(71) Applicant: Henkel AG & Co. KGaA, Duesseldorf (DE)

(72) Inventors: Noriyoshi Kamai, Osaka (JP); Shoko Ito, Osaka (JP); Yasushi Yamada, Osaka (JP); Hitoshi Ikeda, Osaka (JP)

(21) Appl. No.: 15/612,446

(22) Filed: Jun. 2, 2017

Related U.S. Application Data
(63) Continuation of application No. PCT/JP2015/005865, filed on Nov. 26, 2015.

(30) Foreign Application Priority Data
Dec. 17, 2014 (JP) 2014-255229

(51) Int. Cl. C09J 175/14; C08G 18/69; B32B 7/12; C08G 18/76; H01L 31/049; C08G 18/62; C08G 18/73

(52) U.S. Cl. CPC C09J 175/14; C08G 18/6262; C08G 18/69; C08G 18/73; C08G 18/7642; H01L 31/049; B32B 7/12; B32B 2457/10

(57) ABSTRACT

An adhesive for laminated sheets, which is excellent in adhesive strength to a film after curing and long-term hydrolysis resistance at high temperature and high humidity when a laminated sheet is produced, and is also excellent in adhesive property at low temperature. Disclosed is an adhesive for laminated sheets, which comprises a urethane resin obtainable by mixing an acrylic polyol with an isocyanate compound, and also has a chemical structure derived from a diene polymer, wherein the diene polymer has a glass transition temperature of −40° C. or lower. The adhesive for laminated sheets is excellent in adhesive strength to a film after curing and long-term hydrolysis resistance at high temperature and high humidity when a laminated sheet is, produced, and is also excellent in adhesive property at low temperature.

### CROSS-REFERENCE TO RELATED APPLICATIONS

This application claims priority under Article 4 of the Paris Convention based on Japanese Patent Application No. 2014-255229 filed on Dec. 17, 2014 in Japan, the entire content of which is incorporated herein by reference.

### TECHNICAL FIELD

The present invention relates to an adhesive for laminated sheets. The present invention also relates to a laminated sheet obtainable by using the adhesive, and an article obtainable by using the laminated sheet, particularly a solar battery back sheet.

### BACKGROUND

Outdoor materials such as wall protecting materials, roofing materials, solar battery panel materials, window materials, outdoor flooring materials, illumination protection materials, automobile members, and signboards, as well as packaging bags for shampoos, rinses, and foods comprise, as a constituent material, a laminated sheet (or a laminate) obtained by laminating a plurality of films each other using an adhesive. Examples of the film composing the laminated sheet include metal foils, metal plates, and metal deposited films made of metals such as aluminum, copper, and steel; and films made of plastics such as polypropylenes, polyvinyl chlorides, polyesters, fluororesins, and acrylic resins.

As shown in FIG. 1, a laminated sheet 10 is a laminate of a plurality of films 11 and 12, and the films 11 and 12 are laminated by interposing an adhesive 13 therebetween.

Since the laminated sheet is exposed outdoors over a long term, excellent durability is required of the adhesive for laminated sheets. It is required for adhesives for laminated sheets, particularly adhesives for solar battery applications (which convert sunlight into electricity), to have a higher level of durability than a conventional adhesive for laminated sheets.

As shown in FIG. 3, in the case of solar battery applications, the laminated sheet 10 referred to as a back sheet is included in a solar battery module 1, together with a sealing material 20, a solar battery cell 30, and a glass plate 40.

Since the solar battery module 1 is exposed outdoors over a long term, sufficient durability against sunlight is required under conditions of high temperature and high humidity. Particularly, when the adhesive 13 has poor performance, the film 11 can be peeled from the film 12, and thus the appearance of the sheet 10 deteriorates. Therefore, it is required that the adhesive for laminated sheets for the production of the solar battery module does not result in peeling of the film even though the adhesive is exposed to high temperature over a long term.

Patent Document 1 JP 2011-233750 A

Patent Document 2 JP 2012-054396 A

Patent Document 3 JP 2014-019711 A

Patent Documents 1 to 3 disclose, as an example of adhesives for laminated sheets, urethane based adhesives obtained by mixing an isocyanate compound with a polyol compound. All documents disclose, as a component to be mixed with the isocyanate compound, a diene polymer having a hydroxyl group at the end (modified rubber).

Patent Document 1 discloses an adhesive for solar battery back sheets, obtainable by mixing a hydroxyl group-modified butadiene rubber or a hydroxyl group-modified isoprene rubber with an isocyanate component to thereby synthesize a modified rubber having a hydroxyl group at the end, and mixing the modified rubber, a tackifier, and a crosslinking agent (see Patent Document 1 [Claims 1, 3, and 4], and [Examples], etc.).

Patent Document 2 discloses an adhesive for solar battery back sheets, obtainable by synthesizing a modified rubber having a hydroxyl group at the end from a hydroxyl group-modified hydrogenated type butadiene rubber or a hydroxyl group-modified hydrogenated type isoprene rubber, and mixing the modified rubber, a tackifier, and a crosslinking agent (see Patent Document 2 [Claim 1] and [Examples]).

Patent Document 3 discloses a polyurethane based laminate adhesive obtained by mixing an allophanate group-containing polyisocyanate with a polybutadiene polyol or a polyisoprene polyol to thereby synthesize a polyurethane polyol, and mixing the polyurethane polyol with a polyisocyanate (see Patent Document 3 [Claim 1] and [Table 1]).

In recent years, performances required for an adhesive for laminated sheets becomes higher and higher. There is a need for the adhesive for laminated sheets to be not only excellent in durability against high temperature and high humidity required for the adhesive for solar battery back sheets, but also excellent in adhesive strength at low temperature of about 5° C., considering storage of a laminated sheet in cold districts in abroad, dark places in winter, refrigerators, and the like. Furthermore, the laminated sheet should not be easily peeled after curing.

The adhesives for laminated sheets of Patent Documents 1 to 3 are excellent in adhesive strength after curing to some extent. However, it cannot be said that the adhesives completely satisfy severe requirements with respect to hydrolysis resistance at high temperature and high humidity as well as adhesive property at low temperature in recent years.

### SUMMARY OF INVENTION

The present invention has been made so as to solve these problems, and provides an adhesive for laminated sheets, which is excellent in adhesive strength to a film after curing and excellent in long-term hydrolysis resistance at high temperature and high humidity when a laminated sheet (laminate) is produced, and is further also excellent in adhesive property (or adhesiveness) at low temperature; a laminated sheet obtainable by using the adhesive, such as a solar battery back sheet; outdoor materials obtainable by using the laminated sheet such as a solar battery module; and an article such as a packaging bag for shampoos.

The present inventors have intensively studied and found, surprisingly, that when a urethane adhesive synthesized from an acrylic polyol and an isocyanate compound has a chemical structure derived from a specific diene polymer, it is possible to solve the above problem, and thus the present invention has been completed.

That is, the present invention and preferred aspects of the present invention are as follows.

Namely, the present invention provides, in an aspect, an adhesive for laminated sheets, which comprises a urethane resin obtainable by mixing an acrylic polyol with an isocyanate compound, and also has a chemical structure derived from a diene polymer, wherein the diene polymer has a glass transition temperature of −40° C. or lower.

The present invention provides, in an embodiment, the adhesive for laminated sheets, wherein the diene polymer includes a polydiene polyol having a hydroxyl group at the end.

The present invention provides, in another embodiment, the adhesive for laminated sheets, wherein the diene polymer includes (i) a vinyl group and further includes at least one selected from (ii) a vinylene group and (iii) a vinylidene group, wherein the proportion of the vinyl group (i) is 75 mol % or less based on the total of the groups (i) to (iii).

The present invention provides, in a preferred embodiment, the adhesive for laminated sheets, wherein the acrylic polyol is obtainable by the polymerization of a polymerizable monomer, the polymerizable monomer includes a monomer having a hydroxy group and the other monomer, the monomer having a hydroxyl group includes a hydroxyalkyl (meth)acrylate, and the other monomer includes acrylonitrile and a (meth)acrylic ester.

The present invention provides, in a more preferred embodiment, the adhesive for laminated sheets, wherein the isocyanate compound includes at least one selected from aliphatic and alicyclic isocyanates.

The present invention provides, in another aspect, a solar battery back sheet obtainable by using any one of the above adhesives for laminated sheets.

The present invention provides, in a preferred aspect, a solar battery module obtainable by using the above solar battery back sheet.

Since the adhesive for laminated sheets of an embodiment of the present invention comprises a urethane resin obtainable by mixing an acrylic polyol with an isocyanate compound, and also has a chemical structure derived from a diene polymer, wherein the diene polymer has a glass transition temperature of −40° C. or lower, the adhesive for laminated sheets is excellent in both adhesive strength to a film after curing and long-term hydrolysis resistance at high temperature and high humidity when a laminated sheet (laminate) is produced, and is also excellent in adhesive property at low temperature.

The laminated sheet obtainable by using the adhesive for laminated sheets of the present invention is suitable as a solar battery back sheet.

### BRIEF DESCRIPTION OF DRAWINGS

FIG. 1 is a sectional view showing an embodiment of the solar battery back sheet of the present invention.

FIG. 2 is a sectional view showing another embodiment of the solar battery back sheet of the present invention.

FIG. 3 is a sectional view showing an embodiment of the solar battery module of the present invention.

### DESCRIPTION OF EMBODIMENTS

The adhesive for laminated sheets of an embodiment of the present invention includes a urethane resin obtainable by mixing an acrylic polyol with an isocyanate compound, and also has a chemical structure derived from a diene polymer. The diene polymer may be incorporated into the adhesive for laminated sheets by using any method (for example, chemical bond), and may be substituted with an optional substituent on optional position of the diene polymer, or may be unsubstituted.

The urethane resin of an embodiment of the present invention is a polymer obtainable by reacting an acrylic polyol with an isocyanate compound, and has a urethane bond. The urethane resin may include the below-mentioned diene polymer, a silane compound, and other component(s). The diene polymer, the silane compound, and the other component(s) may be added in the case of mixing the acrylic polyol with the isocyanate compound, or may be added to the urethane resin after completion of the reaction between the acrylic polyol and the isocyanate compound.

In the present invention, the “acrylic polyol” refers to a compound obtainable by the addition polymerization reaction of a (meth)acrylate having a hydroxyl group, and has an ester bond on a “side chain”.

The “acrylic polyol” may be either a homopolymer of a (meth)acrylate having a hydroxyl group, or a copolymer of a (meth)acrylate having a hydroxyl group with the “other polymerizable monomer”, and is preferably a copolymer of a (meth)acrylate having a hydroxyl group with the “other polymerizable monomer” from the viewpoint of the adhesive strength and so on. The hydroxyl group of the acrylic polyol reacts with an isocyanate group.

Examples of the “(meth)acrylate having a hydroxyl group” include 2-hydroxyethyl (meth)acrylate, 2-hydroxypropyl (meth)acrylate, 3-hydroxypropyl (meth)acrylate, glycerin mono(meth)acrylate, 4-hydroxybutyl acrylate, and the like.

The “other monomer” is a “radical polymerizable monomer having an ethylenic double bond” except for monomers having a hydroxyl group, and preferably includes acrylonitrile and a (meth)acrylic ester other than the monomers having a hydroxyl group. The other monomer may further include only acrylonitrile and the (meth)acrylic ester in the acrylic polyol, or may further include a radical polymerizable monomer having an ethylenic double bond other than acrylonitrile and the (meth)acrylic ester.

In the adhesive for laminated sheets of an embodiment of the present invention, when the “other monomer” includes acrylonitrile and a (meth)acrylic ester, whereby, the adhesive strength to a film after curing is more increased.

The “(meth)acrylic ester” is a compound obtainable by the condensation reaction of (meth)acrylic acid with a monoalcohol, and has an ester bond. Specific examples thereof include methyl (meth)acrylate, ethyl (meth)acrylate, butyl (meth)acrylate, cyclohexyl (meth)acrylate, 2-ethylhexyl (meth)acrylate, dicyclopentanyl (meth)acrylate, glycidyl (meth)acrylate, isobornyl (meth)acrylate, and the like. In the present invention, it is preferred to include at least one selected from methyl (meth)acrylate, ethyl (meth)acrylate, butyl (meth)acrylate, cyclohexyl (meth)acrylate, and 2-ethylhexyl (meth)acrylate, and it is more preferred to include at least one selected from methyl (meth)acrylate, ethyl (meth)acrylate, and butyl (meth)acrylate.

Examples of the “radical polymerizable monomer having an ethylenic double bond, other than acrylonitrile and (meth)acrylic ester” include, but are not limited to (meth)acrylic acid, styrene, vinyltoluene, and the like.

The “acrylonitrile” is a compound represented by the general formula: CH₂═CH—CN, and is also called acrylic nitrile, acrylic acid nitrile, or vinyl cyanide.

The amount of acrylonitrile in the polymerizable monomers is preferably from 1 to 40 parts by weight, more preferably from 5 to 35 parts by weight, and particularly preferably from 5 to 25 parts by weight, based on 100 parts by weight of the polymerizable monomers. When the amount of the acrylonitrile is within the above range, it is possible to obtain an adhesive for laminated sheets, which shows an excellent coatability and adhesive property to a film after curing.

As long as the objective adhesive for laminated sheets of an embodiment of the present invention can be obtained, there is no particular limitation on the polymerization method of the polymerizable monomer. For example, the above-mentioned polymerizable monomer can be radically polymerized by a conventional solution polymerization method in an organic solvent using an appropriate catalyst. Here, there is no particular limitation on the “organic solvent” as long as it can be used to polymerize the polymerizable monomer, and it does not substantially exert an adverse influence on the properties of the adhesive for laminated sheets after the polymerization reaction. Examples of such solvent include aromatic solvents such as toluene and xylene; alcohol based solvents such as isopropyl alcohol and n-butyl alcohol; ester based solvents such as ethyl acetate and butyl acetate; and combinations thereof.

The polymerization reaction conditions such as reaction temperature, reaction time, type of organic solvents, type and concentration of monomers, stirring rate, as well as the type and concentration of catalysts in the polymerization of the polymerizable monomers can be appropriately selected according to characteristics and so on of the objective adhesive.

The “catalyst” is preferably a compound which can accelerate the polymerization of the polymerizable monomer when added in a small amount and can be used in an organic solvent. Examples of the catalyst include ammonium persulfate, sodium persulfate, potassium persulfate, t-butyl peroxybenzoate, 2,2′-azobisisobutyronitrile (AlBN), and 2,2′-azobis(2-aminodipropane) dihydrochloride, and 2,2′-azobis(2,4-dimethylvarelonitrile), and 2,2′-azobisisobutyronitrile (AlBN) is particularly preferable.

A chain transfer agent can be appropriately used for the polymerization in the present invention so as to adjust the molecular weight. It is possible to use, as the “chain transfer agent”, compounds well-known to those skilled in the art. Examples thereof include mercaptans such as n-dodecylmercaptan (nDM), laurylmethylmercaptan, and mercaptoethanol.

As mentioned above, the acrylic polyol is obtainable by polymerizing the polymerizable monomer. From the viewpoint of coatability of the adhesive, the weight average molecular weight (Mw) of the acrylic polyol is preferably 200,000 or less, and more preferably from 5,000 to 100,000. The weight average molecular weight (Mw) is a value obtained by gel permeation chromatography (GPC) in terms of polystyrene standard. Specifically, the value can be measured using the following GPC apparatus and measuring method. HCL-8220GPC manufactured by TOSOH CORPORATION is used as a GPC apparatus, and RI is used as a detector. Two TSKgel SuperMultipore HZ-M manufactured by TOSOH CORPORATION are used as a GPC column. A sample is dissolved in tetrahydrofuran and the obtained solution is allowed to flow at a flow rate of 0.35 ml/minute and at a column temperature of 40° C., and then the Mw is determined by conversion of an observed molecular weight based on a calibration curve which is obtained by using polystyrene having a monodisperse molecular weight as a standard reference material.

Using a differential scanning calorimeter (SII NanoTechnology DSC6220, manufactured by SII NanoTechnology Inc.), a DSC curve of 10 mg of a sample was determined at a temperature raising rate of 10° C./minute and a temperature of an inflection point of the obtained DSC curve was regarded as a glass transition temperature (Tg) of the acrylic polyol.

In the present invention, the glass transition temperature of the acrylic polyol is preferably from 20° C. or lower, more preferably −55° C. to 10° C., and particularly preferably −30° C. to 0° C., from the viewpoint of the adhesive strength to a film after curing.

The hydroxyl value of the acrylic polyol is preferably from 0.5 to 45 mgKOH/g, more preferably from 1 to 40 mgKOH/g, and particularly preferably from 5 to 20 mgKOH/g. When the hydroxyl value of the acrylic polyol is within the above range, it is possible to obtain an adhesive for laminated sheets, which is excellent in adhesive strength to a film after curing, and hydrolysis resistance at high temperature.

In the present description, the hydroxyl value is a number of mg of potassium hydroxide required to neutralize acetic acid combined with hydroxyl groups when 1 g of a resin is acetylated.

In the present invention, the hydroxyl value is specifically calculated by the following formula (ii).

(ii): Hydroxyl value=[(weight of (meth)acrylate having a hydroxyl group)/(molecular weight of (meth)acrylate having a hydroxyl group)]×(mole number of hydroxyl groups contained in 1 mol of (meth)acrylate monomer having a hydroxyl group)×(formula weight of KOH×1,000)/(weight of the acrylic polyol)

Examples of the isocyanate compound include an aliphatic isocyanate, an alicyclic isocyanate, and an aromatic isocyanate, and there is no particular limitation as long as the objective adhesive for laminated sheets of the present invention can be obtained.

In the present description, the “aliphatic isocyanate” refers to a compound which has a chain-like hydrocarbon chain in which isocyanate groups are directly combined to the hydrocarbon chain. The “aliphatic isocyanate” may have an aromatic ring, however, the aromatic ring is not directly combined with the isocyanate group.

In the present description, the aromatic ring is not included in the cyclic hydrocarbon chain.

The “alicyclic isocyanate” is a compound which has a cyclic hydrocarbon chain and may have a chain-like hydrocarbon chain. The isocyanate group may be either directly combined with the cyclic hydrocarbon chain, or may be directly combined with the chain-like hydrocarbon chain which may be present. The “alicyclic isocyanate” may have an aromatic ring, but the aromatic ring is not directly combined with the isocyanate group.

The “aromatic isocyanate” refers to a compound having an aromatic ring, an isocyanate group being directly combined with the aromatic ring. Therefore, even if the aromatic ring is included in the molecule, a compound in which the isocyanate group is not directly combined with the aromatic ring is classified into an aliphatic isocyanate or an alicyclic isocyanate.

Therefore, 4,4′-diphenylmethane diisocyanate (OCN—C₆H₄—CH₂—C₆H₄—NCO) corresponds to the aromatic isocyanate since the isocyanate group is directly combined with the aromatic ring. Whereas, for example, xylylene diisocyanate (OCN—CH₂—C₆H₄—CH₂—NCO) has an aromatic ring, however, the isocyanate group is not directly combined with the aromatic ring, but is combined with a methylene group, so that xylylene diisocyanate corresponds to the aliphatic isocyanate. Two or more benzene rings may be fused in the aromatic ring.

Examples of the aliphatic isocyanate include 1,4-diisocyanatobutane, 1,5-diisocyanatopentane, 1,6-diisocyanatohexane (hereinafter referred to as HDI), 1,6-diisocyanato-2,2,4-trimethylhexane, methyl 2,6-diisocyanatohexanoate (lysine diisocyanate), 1,3-bis(isocyanatomethyl)benzene (xylylene diisocyanate), and the like.

Examples of the alicyclic isocyanate include 5-isocyanato-1-isocyanatomethyl-1,3,3-trimethylcyclohexane (isophorone diisocyanate), 1,3-bis(isocyanatomethyl)cyclohexane (hydrogenated xylylene diisocyanate), bis(4-isocyanatocyclohexyl)methane (hydrogenated diphenylmethane diisocyanate), 1,4-diisocyanatocyclohexane, and the like.

Examples of the aromatic isocyanate include 4,4′-diphenylmethane diisocyanate, p-phenylene diisocyanate, m-phenylene diisocyanate, and the like. These isocyanate compounds can be used alone or in combination.

In the present invention, the isocyanate compound is not particularly limited as long as the objective urethane adhesive of the present invention can be obtained, and is preferably selected from aliphatic isocyanates and alicyclic isocyanates from the viewpoint of weatherability. The isocyanate compound is preferably HDI, isophorone diisocyanate, or xylylene diisocyanate, and particularly preferably a trimer of HDI.

The urethane resin of an embodiment of the present invention is obtainable by reacting an acrylic polyol with an isocyanate compound. In the reaction, a known method can be used and the reaction can be generally performed by mixing the acrylic polyol with the isocyanate compound. There is no particular limitation on the mixing method as long as the urethane resin of an embodiment of the present invention can be obtained.

### Diene Polymer

In the present description, the diene polymer refers to a compound obtainable by the polymerization of a diene monomer having two ethylenic double bonds. The adhesive for laminated sheets of an embodiment of the present invention is excellent in adhesive property at low temperature because of having a chemical structure derived from the diene polymer.

The diene polymer may have a functional group as long as it does not exert an adverse influence on the objective adhesive for laminated sheets of the present invention. As mentioned below, double bonds between carbon atoms may be at least partly or entirely saturated by hydrogenation.

The diene polymer is obtainable by the polymerization of a diene monomer. Examples of the diene monomer include conjugated diene monomers such as butadiene, isoprene, chloroprene, cyanobutadiene, pentadiene, and the like. In the present invention, the diene monomer is preferably butadiene and isoprene, and most preferably butadiene in consideration of balance among adhesive strength to a film after curing, long-term hydrolysis resistance at high temperature and high humidity, and adhesive property at low temperature.

The diene polymer is obtainable, for example, by polymerizing these diene monomers using known polymerization methods such as suspension polymerization, bulk polymerization, solution polymerization, and emulsion polymerization methods. Examples of the polymer include polybutadiene, polyisoprene, polychloroprene, polycyanobutadiene, polypentadiene and the like. The diene polymer is preferably polybutadiene or polyisoprene, and particularly preferably polybutadiene.

Examples of a functional group, which can be possessed by the diene polymer, include an acid anhydride group such as a maleic anhydride group, a carboxyl group, a maleic acid group, an amino group, an imino group, an alkoxysilyl group, a silanol group, a silylether group, a hydroxyl group, an epoxy group, or the like. A hydroxyl group is most preferable as these functional groups.

In the present invention, the diene polymer preferably include a polymer having a hydroxyl group, and particularly preferably a polydiene polyol having a hydroxyl group at the end of the diene polymer.

The above-mentioned polydiene polyol can be obtained by modifying the molecular end of the diene polymer into a hydroxyl group using a known method.

In the present invention, specific examples of the polydiene polyol include polybutadiene polyol, polyisoprene polyol, polychloroprene polyol, polycyanobutadiene polyol, and polypentadiene polyol, and polyisoprene polyol and polybutadiene polyol are preferable.

The polydiene polyol may be a hydrogenated product obtained by hydrogenating a double bond, and the hydrogenation rate of the double bond can be appropriately selected.

In consideration of balance among adhesive strength to a film after curing, long-term hydrolysis resistance at high temperature and high humidity, and adhesive property at low temperature of the adhesive for laminated sheets of an embodiment of the present invention, the polydiene polyol is preferably polybutadiene polyol and polyisoprene polyol, and most preferably polybutadiene polyol.

A hydroxyl value of the polydiene polyol is preferably 4 mgKOH/g or more, more preferably from 5 mgKOH/g to 250 mgKOH/g, and most preferably from 5 mgKOH/g to 150 mgKOH/g.

The hydroxyl value can be obtained by an acetylation method, a phthalation method, or the like in accordance with the method A or B of JIS K 1557-1.

The glass transition temperature of the diene polymer is −40° C. or lower, particularly preferably from −45 to −75° C., and most preferably from −50 to −60° C. The glass transition temperature of the diene polymer is measured by DSC in the same manner as in glass transition temperature of the acrylic polyol.

Since the glass transition temperature of the diene polymer is within the above range, the adhesive for laminated sheets of an embodiment of the present invention is excellent in adhesive property at low temperature, and long-term hydrolysis resistance at high temperature and high humidity.

The diene polymer has (i) a vinyl group [—CH═CH₂], and also has at least one selected from (ii) a vinylene group [—CH═CH—], and (iii) a vinylidene group [—C(═CH₂)—]. The vinylene group includes a cis-type group and a trans-type group. The proportion of the vinyl group (i) is preferably 75 mol % or less, more preferably from 1 to 65 mol %, and most preferably from 10 to 65 mol %, based on 100 mol % of the total of (i) to (iii).

When the vinyl group (i) exists within the above range, the adhesive for laminated sheets of an embodiment of the present invention is excellent in long-term hydrolysis resistance at high temperature and high humidity.

The proportion (mol %) of the vinyl group (i) of the diene polymer can be calculated using an integral ratio of a peak (or a ratio of a peak area) of each proton of a vinyl group, a vinylene group, and a vinylidene group obtained by the measurement of ¹H-NMR (AVANCE^{III}-600 (trade name) manufactured by Bruker Biospin).

The number average molecular weight (Mn) of the diene polymer is preferably 500 or more, more preferably from 1,000 to 25,000, and most preferably from 1,000 to 20,000.

The number average molecular weight of the diene polymer is obtained by GPC in the same manner as in the weight average molecular weight of the acrylic polyol. When the number average molecular weight of the diene polymer is within the above range, the adhesive for laminated sheets of an embodiment of the present invention is excellent in adhesive strength to a film after curing.

In the case of synthesizing a urethane resin, the diene polymer may be added together with an acrylic polyol and an isocyanate compound, or may be added after an acrylic polyol is reacted with an isocyanate compound to thereby synthesize a urethane resin.

When the diene polymer is a polydiene polyol, it is added together with an acrylic polyol and an isocyanate compound to form a urethane resin. In this case, the urethane resin has a chemical structure derived from the diene polymer.

The adhesive for laminated sheets of an embodiment of the present invention preferably includes a silane compound.

It is possible to use, as the silane compound, for example, (meth)acryloxyalkyltrialkoxysilanes, (meth)acryloxyalkylalkylalkoxysilanes, vinyltrialkoxysilanes, vinylalkylalkoxysilanes, epoxysilanes, mercaptosilanes, and isocyanuratesilanes, but the silane compound is not limited only to these silane compounds.

Examples of the “(meth)acryloxyalkyltrialkoxysilanes” include 3-(meth)acryloxypropyltrimethoxysilane, 3-(meth)acryloxypropyltriethoxysilane, 4-(meth)acryloxyethyltrimethoxysilane, and the like.

Examples of the “(meth)acryloxyalkylalkylalkoxysilanes” include 3-(meth)acryloxypropylmethyldimethoxysilane, 3-(meth)acryloxypropylmethyldiethoxysilane, 3-(meth)acryloxypropylethyldiethoxysilane, 3-(meth)acryloxyethylmethyldimethoxysilane, and the like.

Examples of the “vinyltrialkoxysilanes” include vinyltrimethoxysilane, vinyltriethoxysilane, vinyldimethoxyethoxysilane, vinyltri(methoxyethoxy)silane, vinyltri(ethoxymethoxy)silane, and the like.

Examples of the “vinylalkylalkoxysilanes” include vinylmethyldimethoxysilane, vinylethyldi(methoxyethoxy)silane, vinyldimethylmethoxysilane, vinyldiethyl(methoxyethoxy)silane, and the like.

The “epoxysilanes” can be classified, for example, into glycidyl based silanes and epoxycyclohexyl based silanes. The “glycidyl based silanes” have a glycidoxy group, and specific examples thereof include 3-glycidoxypropylmethyldiisopropenoxysilane, 3-glycidoxypropyltrimethoxysilane, 3-glycidoxypropyltriethoxysilane, 3-glycidoxypropyldiethoxysilane, and the like.

The “epoxycyclohexyl based silanes” have a 3,4-epoxycyclohexyl group, and specific examples thereof include 2-(3,4-epoxycyclohexyl)ethyltrimethoxysilane, 2-(3,4-epoxycyclohexyl)ethyltriethoxysilane, and the like.

Examples of the “mercaptosilanes” include 3-mercaptopropyltrimethoxysilane, 3-mercaptopropyltriethoxysilane, and the like.

Examples of the “isocyanuratesilanes” include tris(3-(trimethoxysilyl)propyl)isocyanurate, and the like.

In the present invention, the silane compound is preferably an epoxysilane based compound, and the epoxysilane based compound is preferably 3-glycidoxypropyltrimethoxysilane or 3-glycidoxypropyltriethoxysilane.

The adhesive for laminated sheets of an embodiment of the present invention exhibits more excellent adhesive strength to a film after curing by inclusion of the silane compound.

The adhesive for laminated sheets of an embodiment of the present invention can further contain other components.

There is no particular limitation on timing of the addition of the “other components” to the adhesive for laminated sheets as long as an adverse influence is not exerted on the object of the present invention. For example, the other components may be added together with the acrylic polyol and the isocyanate compound in the synthesis of the urethane resin, or may be added after synthesizing the urethane resin by reacting the acrylic polyol with the isocyanate compound.

Examples of the “other component” include a tackifier resin, a pigment, a plasticizer, a flame retardant, a wax and the like.

Examples of the “tackifier resin” include styrene based resins, terpene based resins, aliphatic petroleum resins, aromatic petroleum resins, rosin esters, acrylic resins, polyester resins (excluding polyester polyols), and the like.

Examples of the “pigment” include titanium oxide, carbon black, and the like.

Examples of the “plasticizer” include dioctyl phthalate, dibutyl phthalate, diisononyl adipate, dioctyl adipate, mineral spirits, and the like.

Examples of the “flame retardant” include halogen based flame retardants, phosphorous based flame retardants, antimony based flame retardants, metal hydroxide based flame retardants, and the like.

Examples of the “catalyst” include metal catalysts, for example, tin catalysts (trimethyltin laurate, trimethyltin hydroxide, stannous octoate, dibutyltin dilaurate, dibutyltin diacetate, dibutyltin maleate, etc.) lead based catalysts (lead oleate, lead naphthenate, lead octoate, etc.), other metal catalysts (naphthenic acid metal salt such as cobalt naphthate, etc.), and amine based catalysts such as triethylenediamine, tetramethylethylenediamine, tetramethylheylenediamine, diazabicycloalkenes, and dialkylaminoalkylamines.

The “wax” is preferably a wax such as paraffin waxes and microcrystalline waxes.

Viscosity of the adhesive for laminated sheets of an embodiment of the present invention is measured by using a rotational viscometer (Model BM, manufactured by TOKIMEC Inc.). The adhesive preferably has solution viscosity (solid content of 40%) of less than 4,000 mPa·s. When the solution viscosity at the solid content of 40% is less than 4,000 mPa·s, since it is possible to satisfactorily maintain applicability (or coatability) of the adhesive, there is no need to further add a solvent so as to decrease the viscosity. If a solvent is further added, the adhesive may be applied at low solid component concentration to thereby deteriorate the appearance and productivity of laminated sheets. Therefore, possibility of the deteriorations of the appearance and the productivity may be reduced.

The adhesive for laminated sheets of an embodiment of the present invention can be produced by mixing the above-mentioned urethane resin, and other components which may be optionally added. There is no particular limitation on the mixing method as long as the objective adhesive for laminated sheets of an embodiment of the present invention can be obtained. There is also no particular limitation on the order of mixing the components. The adhesive for laminated sheets of an embodiment of the present invention can be produced without requiring a special mixing method and a special mixing order. The obtained adhesive for laminated sheets is excellent in overall balance among adhesive strength to a film after curing, long-term hydrolysis resistance at high temperature and high humidity, and adhesive property at low temperature.

It is required for an adhesive for producing solar battery modules to have adhesive property and hydrolysis resistance at high levels. The adhesive for laminated sheets of an embodiment of the present invention is excellent in adhesive strength to a film after curing, long-term hydrolysis resistance at high temperature and high humidity, adhesive property at low temperature, so that the adhesive for laminated sheets is suitable as an adhesive for solar battery back sheets.

In the case of producing a solar battery back sheet, the adhesive of an embodiment of the present invention is applied to a film. The application can be performed by various methods such as gravure coating, wire bar coating, air knife coating, die coating, lip coating, and comma coating methods. Plural films coated with the adhesive for laminated sheets of an embodiment of the present invention are laminated each other, and thus a solar battery back sheet can be produced.

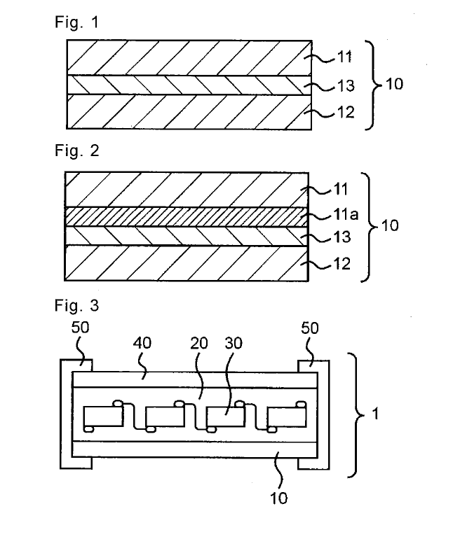

An example of the solar battery back sheet as an embodiment of laminated sheets of the present invention is shown in each of FIGS. 1 to 3, but the present invention is not limited to these embodiments.

FIG. 1 is a sectional view of a solar battery back sheet of an embodiment of the present invention. The solar battery back sheet 10 is formed of two films and an adhesive for laminated sheets 13 interposed therebetween, and the two films 11 and 12 are laminated each other using the adhesive for laminated sheets 13. The films 11 and 12 may be made of either the same or different material. In FIG. 1, the two films 11 and 12 are laminated each other, or three or more films may be laminated one another.

Another embodiment of the solar battery back sheet according to the present invention is shown in FIG. 2. In FIG. 2, a foil film 11a is formed between the film 11 and the adhesive for laminated sheets 13. For example, FIG. 2 shows an embodiment in which a metal thin film 11a is formed on the surface of the film 11 when the film 11 is a plastic film. The metal thin film 11a can be formed on the surface of the plastic film 11 by vapor deposition, and the solar battery back sheet of FIG. 2 can be obtained by laminating the metal thin film 11, on which surface the metal thin film 11a is formed, with the film 12 by interposing the adhesive for laminated sheets 13 therebetween.

Examples of the metal to be deposited on the plastic film include aluminum, steel, copper and the like. It is possible to impart barrier properties to the plastic film by subjecting the film to vapor deposition. Silicon oxide or aluminum oxide is used as a vapor deposition material. The plastic film 11 as a base material may be either transparent, or white- or black-colored.

A plastic film made of a polyvinyl chloride, a polyester, a fluororesin or an acrylic resin is used as the film 12. In order to impart heat resistance, weatherability, rigidity, insulating properties, and the like, it is particularly preferred to use a polyethylene terephthalate film or a polybutylene terephthalate film. The films 11 and 12 may be either transparent or colored.

The deposited thin film 11a of the film 11 and the film 12 are laminated each other using the adhesive for solar battery back sheets 13 of an embodiment of the present invention, and the films 11 and 12 are often laminated each other by a dry lamination method. Therefore, it is required that the adhesive for solar battery back sheets 13 of an embodiment of the present invention is excellent in initial adhesion to a film during lamination and is also excellent in adhesion to a film after curing.

FIG. 3 shows a sectional view of an example of a solar battery module of an embodiment of the present invention. In FIG. 3, it is possible to obtain a solar battery module 1 by laying a glass plate 40, a sealing material 20 such as an ethylene-vinyl acetate resin (EVA), plural solar battery cells 30 which are commonly connected with each other so as to generate a desired voltage, and a back sheet 10 over one another, and then fixing these members 10, 20, 30 and 40 using a spacer 50.

As mentioned above, since the back sheet 10 is a laminate of the plurality of the films 11 and 12, even though the back sheet 10 is exposed outdoors over a long term, the urethane adhesive 13 causes no peeling of the films 11 and 12 and is excellent in long-term hydrolysis resistance at high temperature and high humidity, and adhesive property at low temperature.

### Examples

The present invention will be described below by way of Examples and Comparative Examples, and these Examples are merely for illustrative purposes and are not meant to be limiting on the present invention.

### Synthesis of Acrylic Polyol

### Synthetic Example 1 Acrylic Polyol (A1) (Polymer 1)

In a four-necked flask equipped with a stirring blade, a thermometer, and a reflux condenser, 100 parts by weight of ethyl acetate (manufactured by Wako Pure Chemical Industries, Ltd.) was charged and refluxed at about 80° C. In the flask, 1.0 part by weight of 2,2′-azobisisobutyronitrile as a polymerization initiator was added and a mixture of monomers in each amount shown in Table 1 was continuously added dropwise over 1 hour and 30 minutes. After heating for additional 1 hour, a step of adding 0.2 part by weight of 2,2′-azobisisobutyronitrile and reacting for 1 hour was repeated four times to obtain a solution of an acrylic polyol (polymer 1) having a non-volatile content (solid content) of 50.0%.

The composition of polymerizable monomer components for the production of the polymer 1 and physical properties of the obtained polymer 1 are shown in Table 1.

### Synthetic Examples 2 and 3

In the same manner as in Synthetic Example 1, except that the composition of the monomers used in the synthesis of the acrylic polyol was changed as shown in Table 1, a polymer 2 (A2) and a polymer 3 (A3) were obtained. Physical properties of the obtained polymers 2 and 3 are shown in Table 1.

The polymerizable monomers and other components in Table 1 are shown below.

Methyl methacrylate (MMA): manufactured by Wako Pure Chemical Industries, Ltd.

Butyl acrylate (BA): manufactured by Wako Pure Chemical Industries, Ltd.

Acrylonitrile (AN): manufactured by Wako Pure Chemical Industries, Ltd.

2-Hydroxyethyl methacrylate (HEMA): manufactured by Wako Pure Chemical Industries, Ltd.

Styrene (St): manufactured by Wako Pure Chemical Industries, Ltd.

TABLE 1

| | Synthetic Examples | | |
|---|---|---|---|
| | A1 | A2 | A3 |
| St | 3 | 3 | 3 |
| MMA | 27 | 27 | 20 |
| BA | 56 | 56.5 | 61 |
| AN | 12 | 12 | 12 |
| HEMA | 2 | 1.5 | 4 |
| Tg (° C.) of acrylic polyol | −5.4 | −4.6 | −9.9 |
| Hydroxyl value | 8.6 | 6.5 | 17.2 |
| (mgKOH/g) | | | |
| Polymer | 1 | 2 | 3 |

In addition to (A1) to (A3) shown in Table 1, a commercially available polyol (polymer 4) (A′4) was used. Details of the polyol (A′4) are as follows.

(A′4) polyester polyol (LOCKTITE LIOFOL LA2790 (trade name) manufactured by Henkel Japan Ltd., Tg: −12° C., hydroxyl value: 13.6 mgKOH/g)

### Production of Adhesive for Laminated Sheets

The above-mentioned component (A), and the below-mentioned component (B), component (C), and component (D) were mixed to produce adhesives for laminated sheets.

(B) Isocyanate compound

(B1) Aliphatic isocyanate compound 1 (hexamethylene diisocyanate trimer: Sumidur N3300 (trade name) manufactured by Sumika Bayer Urethane Co., Ltd.)

(B2) Aliphatic isocyanate compound 2 (xylene diisocyanate: Takenato 500 (trade name) manufactured by Mitsui Chemicals, Incorporated.)

(B′3) Aromatic isocyanate compound 3 (trimethylolpropane adduct of toluene diisocyanate: Coronate L (trade name) manufactured by TOSOH CORPORATION (Former NIPPON POLYURETHANE INDUSTRY CO. LTD.)

(C) Diene polymer

(C1) Polyisoprene polyol 1 (Poly ip (trade name) manufactured by Idemitsu Kosan Co., Ltd., Tg: −57° C., proportion of vinyl group: 10 mol %)

(C2) Polybutadiene polyol 2 (Poly bd R-45HT (trade name) manufactured by Idemitsu Kosan Co., Ltd., Tg: −75° C., proportion of vinyl group: 22 mol %)

(C3) Polybutadiene polyol 3 (Poly bd R-15HT (trade name) manufactured by Idemitsu Kosan Co., Ltd., Tg: −70° C., proportion of vinyl group: 22 mol %)

(C4) Polybutadiene polyol 4 (Krasol LBHP3000 (trade name) manufactured by CRAY VALLEY HSC, Tg: −45° C., proportion of vinyl group: 65 mol %)

(C5) Hydrogenated polybutadiene polyol 5 (Krasol HLBHP3000 (trade name) manufactured by CRAY VALLEY HSC, hydrogenated Krasol LBHP3000, Tg: −55° C., proportion of vinyl group: less than 2 mol %)

(C′6) Polybutadiene polyol 6 (NISSO PB G2000 (trade name) manufactured by Nippon Soda Co., Ltd., Tg: −19° C., proportion of vinyl group: 91 mol %)

(C′7) Polybutadiene polyol 7 (NISSO PB G1000 (trade name) manufactured by Nippon Soda Co., Ltd., Tg: −25° C., proportion of vinyl group: 91 mol %)

(C′8) 1,2-Polybutadiene homopolymer 8 (NISSO PB B2000 (trade name) manufactured by Nippon Soda Co., Ltd., Tg: −29° C., proportion of vinyl group: 90 mol %)

### Measurement of Glass Transition Temperature (Tg)

A glass transition temperature (Tg) of components (A) and (C) was measured using a differential scanning calorimeter (SII NanoTechnology DSC6220, manufactured by SII NanoTechnology Inc.). A DSC curve of 10 mg of a sample was obtained at a temperature raising rate of 10° C./minute and a temperature of an inflection point of the obtained DSC curve was regarded as Tg to be determined.

### Measurement of Molar Amount of Vinyl Group

The proportion of a vinyl group of a component (C) was determined by the following procedure. That is, a CDCl₃ solution of each component (C) was prepared and ¹H-NMR thereof was measured using AVANCE^{III}-600 (trade name) manufactured by Bruker Biospin, and then the proportion was calculated based on the obtained peak integral (or area) ratio.

In the case of polybutadiene, it was considered that a peak at δ4.91 to 4.97 is a peak based on protons of [═CH₂] of vinyl groups [—CH═CH2] of 1,2-adduct, and a peak at δ5.33 to 5.40 is a peak based on protons of cis- and trans-vinylene groups [—CH═CH—] of 1,4-adduct.

In the case of polyisoprene, it was considered that a peak at δ5.73 to 5.75 is a peak based on protons of [—CH═] of vinyl groups of 1,2-adduct, a peak at 5.11 to 5.12 is a peak based on protons [50 CH—] of cis- and trans-(methyl-substituted)vinylene groups [—C(CH₃)≡CH—] of 1,4-adduct, and peak at δ4.63 to 4.73 is a peak based on protons of [═CH₂] of vinylidene groups [—C(═CH₂)—] of 3,4-adduct.

### (D) Silane Compound

(D1) 3-Glycidoxypropyltriethoxysilane (GLYEO (trade name) manufactured by EVONIK)

(D2) 3-Glycidoxypropyltrimethoxysilane (GLYMO (trade name) manufactured by EVONIK)

### Example 1

As shown in Table 2, 93.5 g of (A1) polymer 1 [ethyl acetate solution (solid content of 50.0% by weight) of 187.0 g of a polymer 1 (A1)], 3.31 g of an aliphatic isocyanate compound 1 (B1), 1.76 g of an aliphatic isocyanate compound 2 (B2), 0.47 g of a polyisoprene polyol 1 (C1), and 0.94 g of 3-glycidoxypropyltriethoxysilane (D1) were weighed and mixed, and then an ethyl acetate solution was added so that the solid content becomes 35% to produce an adhesive for laminated sheets of Example 1.

### Examples 2 to 9 and Comparative Examples 1 to 5

In the same manner as in Example 1, components (A) to (D) were mixed according to the formulations shown in Tables 2 to 4 to produce adhesives for laminated sheets of Examples 2 to 9 and Comparative Examples 1 to 5.

TABLE 2

| | | | Examples | | | | |
|---|---|---|---|---|---|---|---|
| | | | 1 | 2 | 3 | 4 | 5 |
| (A) Polyol | | A1 | 93.5 | 93.5 | 93.5 | | |
| component | | A2 | | | | 94.7 | 94.7 |
| | | A3 | | | | | |
| | | A′4 | | | | | |
| (B) Isocyanate | | B1 | 3.31 | 3.31 | 3.31 | 2.52 | 2.52 |
| compound | | B2 | 1.76 | 1.76 | 1.76 | 1.33 | 1.33 |
| | | B′3 | | | | | |
| (C) Diene | | C1 | 0.47 | | | 0.47 | |
| polymer | | C2 | | 0.47 | | | |
| | | C3 | | | 0.47 | | |
| | | C4 | | | | | 0.47 |
| | | C5 | | | | | |
| | | C′6 | | | | | |
| | | C′7 | | | | | |
| | | C′8 | | | | | |
| Com- | Tg Pro- | ° C. | −57 | −75 | −70 | −57 | −45 |
| ponent | portion | mol | 10 | 22 | 22 | 10 | 65 |
| (C) | of vinyl | % | | | | | |
| | group | | | | | | |

| | | | | | | |
|---|---|---|---|---|---|---|
| (D) Silane | D1 | 0.94 | 0.94 | 0.94 | 0.95 | 0.95 |
| compound | D2 | | | | | |

| | | | | | |
|---|---|---|---|---|---|
| Strength after curing | Good | Good | Good | Good | Good |
| (N/15 mm) | | | | | |
| Low temperature | Good | Good | Normal | Good | Normal |
| (5° C.) adhesive | | | | | |
| strength (N/15 mm) | | | | | |
| Hydrolysis resistance | A | B | C | A | B |

TABLE 3

| | | | Examples | | | |
|---|---|---|---|---|---|---|
| | | | 6 | 7 | 8 | 9 |
| (A) Polyol | | A1 | | 93.5 | 94.4 | |
| component | | A2 | 94.7 | | | |
| | | A3 | | | | 89.1 |
| | | A′4 | | | | |
| (B) Isocyanate | | B1 | 2.52 | 3.31 | 3.34 | 6.29 |
| compound | | B2 | 1.33 | 1.76 | 1.77 | 3.33 |
| | | B′3 | | | | |
| (C) Diene | | C1 | | 0.47 | 0.47 | 0.45 |
| polymer | | C2 | | | | |
| | | C3 | | | | |
| | | C4 | | | | |
| | | C5 | 0.47 | | | |
| | | C′6 | | | | |
| | | C′7 | | | | |
| | | C′8 | | | | |
| Com- | Tg Pro- | ° C. | −55 | −57 | −57 | −57 |
| ponent | portion | mol | <2 | 10 | 10 | 10 |
| (C) | of vinyl | % | | | | |
| | group | | | | | |

| | | | | | |
|---|---|---|---|---|---|
| (D) Silane | D1 | 0.95 | | — | 0.89 |
| compound | D2 | | 0.94 | — | |

| | | | | |
|---|---|---|---|---|
| Strength after curing | Good | Good | Normal | Good |
| (N/15 mm) | | | | |
| Low temperature | Normal | Good | Good | Good |
| (5° C.) adhesive | | | | |
| strength (N/15 mm) | | | | |
| Hydrolysis resistance | B | A | B | C |

TABLE 4

| | | | Comparative Examples | | | | |
|---|---|---|---|---|---|---|---|
| | | | 1 | 2 | 3 | 4 | 5 |
| (A) Polyol | | A1 | 94.0 | | | | |
| component | | A2 | | 94.7 | 94.7 | 94.7 | |
| | | A3 | | | | | |
| | | A′4 | | | | | 89.5 |
| (B) Isocyanate | | B1 | 3.33 | 2.52 | 2.52 | 2.52 | |
| compound | | B2 | 1.77 | 1.33 | 1.33 | 1.33 | |
| | | B′3 | | | | | 9.58 |
| (C) Diene | | C1 | | | | | 0.32 |
| polymer | | C2 | | | | | |
| | | C3 | | | | | |
| | | C4 | | | | | |
| | | C5 | | | | | |
| | | C′6 | | 0.47 | | | |
| | | C′7 | | | 0.47 | | |
| | | C′8 | | | | 0.47 | |
| Com- | Tg Pro- | ° C. | — | −19 | −25 | −29 | −57 |
| ponent | portion | mol | — | 91 | 91 | 90 | 10 |
| (C) | of vinyl | % | | | | | |
| | group | | | | | | |

| | | | | | | |
|---|---|---|---|---|---|---|
| (D) Silane | D1 | 0.94 | 0.95 | 0.95 | 0.95 | 0.64 |
| compound | D2 | | | | | |

| | | | | | |
|---|---|---|---|---|---|
| Strength after curing | Good | Good | Good | Good | Good |
| (N/15 mm) | | | | | |
| Low temperature | Bad | Normal | Normal | Good | Normal |
| (5° C.) adhesive | | | | | |
| strength (N/15 mm) | | | | | |
| Hydrolysis resistance | B | D | D | D | D |

### Production of Laminated Sheet

The adhesive for laminated sheets of Example 1 was applied on a transparent polyethylene terephthalate (PET) sheet (polyester film: OE300EW36 (trade name) manufactured by Mitsubishi Chemical Corporation) so that the weight of the solid component became 10 g/m², and then dried at 80° C. for 5 minutes.

A surface-treated PET film (SHINEBEAM Q3215 (trade name) manufactured by TOYOBO CO., LTD.) was laid on the PET sheet so as to cover the adhesive coated surface of the PET sheet with the surface-treated surface of the PET film. Using a hot rolling press, both the PET sheet and film were pressed under a clamping pressure of 0.9 MPa at a rate of 5 m/min to obtain a laminated sheet.

### Evaluation

### 1. Measurement of Strength After Curing

A laminated sheet was cured at 50° C. for 120 hours. After curing, the laminated sheet was cut out into pieces of 15 mm in width. Using a tensile strength testing machine (TENSILON®-250 (trade name) manufactured by ORIENTEC Co., Ltd.), a peel test was carried out and the adhesive strength was measured.

The peel test was performed under the condition of a tensile speed of 100 mm/min and a peel direction of 180° after maintaining in a room temperature environment at 23° C. for 24 hours or longer. The evaluation criteria are as follows.

Good: 10 N/15 mm or more

Normal: 8 N/15 mm or more and less than 10 N/15 mm

Bad: less than 8 N/15 mm

### 2. Measurement of Adhesive Strength at Low Temperature

A laminated sheet produced in the same manner as mentioned above was cured at 50° C. for 120 hours. After curing, the laminated sheet was cut out into pieces of 15 mm in width. Using an autograph equipped with a constant temperature bath (Autograph AGS-X/TCR1A (trade name) manufactured by Shimadzu Corporation), a peel test was performed and the adhesive strength was measured.

The peel test was performed under the condition of a tensile speed of 100 mm/min and a peel direction of 180° after maintaining at 5° C. for about 2 hours. The evaluation criteria are as follows.

Good: 6 N/15 mm or more

Normal: 3 N/15 mm or more and less than 6 N/15 mm

Bad: less than 3 N/15 mm

### 3. Hydrolysis Resistance

Hydrolysis resistance was evaluated by a promotion evaluation method using pressurized steam.

A laminated sheet produced in the same manner as mentioned above was cured at 50° C. for 120 hours. After curing, the laminated sheet was cut out into pieces of 15 mm in width and then left to stand in a high pressure cooker (Autoclave SP300 (trade name) manufactured by Yamato Scientific Co., Ltd) at 121° C. in a pressurized atmosphere under 0.1 MPa for 48 hours. Thereafter, the laminated sheet was taken out from the high pressure cooker and cured in a room temperature environment for one day. After curing, the laminated sheet was cut out into test pieces of 15 mm in width and 8 cm in length. Using the test pieces, a hand peel test was performed.

The hand peel test is a test in which each test piece is peeled into a base material and an adherend (or two adherends, specifically PET sheet and PET film in this test piece) by hands of the same measurer without using a machine, and an adhesive is evaluated in a peeled state. When adhesive property of the adhesive is satisfactorily kept, the adherend or the base material is fractured (that is, material fracture occurs) in the case of peeling the adherend. When adhesive property of the adhesive deteriorates, the adhesive itself is fractured without causing material fracture of the adherend or the base material, or peeling occurs between the adhesive and the adherend or the base material. The peel length of the adherend and the state of material fracture were visually observed by the measurer, and hydrolysis resistance of the adhesive for laminated sheets was evaluated. The evaluation criteria are as follows.

A: Material fracture occurred when peel length of adherend is less than 0.5 cm.

B: Material fracture occurred when peel length of adherend is 0.5 cm or more and less than 1.5 cm.

C: Material fracture occurred when peel length of adherend is 1.5 cm or more and less than 3 cm.

D: Material fracture did not occur even when peel length of adherend is more than 3 cm.

As shown in Tables 2 and 3, the adhesives for laminated sheets of Examples 1 to 9 have high adhesive force in a low temperature atmosphere, and are also excellent in adhesive property to a film after curing, and excellent in hydrolysis resistance at high temperature and high humidity. The adhesives for laminated sheets of Examples are excellent in the above-mentioned performances, can be sufficiently used as an adhesive for packaging bags and an adhesive for outdoor materials, which require durability at high temperature and high humidity in an extremely high level, and can be sufficiently used as particularly an adhesive for solar battery back sheets.

Whereas, the adhesive for laminated sheets of Comparative Example 1 does not have a chemical structure derived from a diene polymer as shown in Table 4, and is therefore inferior in low temperature adhesive property. The adhesives for laminated sheets of Comparative Examples 2 to 4 cannot improve low temperature adhesive property and hydrolysis resistance in a balanced manner since the glass transition temperature of the diene polymer is higher than −40° C. The adhesive for laminated sheets of Comparative Example, 5 is inferior in hydrolysis resistance since the urethane resin is not synthesized from an acrylic polyol.

The present invention provides an adhesive for laminated sheets. The adhesive for laminated sheets of an embodiment of the present invention exhibits excellent adhesive strength under low temperature environments, and is also excellent in adhesive property to a film after curing. Furthermore, the adhesive for laminated sheets is excellent in long-term hydrolysis resistance at high temperature and high humidity and therefore exhibits extremely high durability against (or under) severe environments, and thus the adhesive for laminated sheets can be suitably used as an adhesive for packaging bags used for shampoos, rinses, and foods, as well as an adhesive for outdoor materials used for solar battery modules and the like.

### DESCRIPTION OF REFERENCE NUMERALS

1: Solar battery module, 10: Back sheet, 11: Film, 11a: Deposited thin film, 12: Film, 13: Adhesive layer, 20: Sealing material (EVA), 30: Solar battery cell, 40: Glass plate, 50: Spacer

1. An adhesive for bonding films to form a laminated sheet comprising a urethane resin obtained by mixing an acrylic polyol, an isocyanate compound and a diene polymer and the diene polymer has a glass transition temperature of −40° C. or lower.

2. The adhesive according to claim 1, wherein the diene polymer comprises a polydiene polyol.

3. The adhesive according to claim 1, wherein the diene polymer includes (i) a vinyl group and further includes at least one group selected from (ii) a vinylene group and (iii) a vinylidene group, wherein
the proportion of the vinyl group (i) is 75 mol % or less based on the total of the groups (i) to (iii).

4. The adhesive according to claim 1, wherein the acrylic polyol is obtained by the polymerization of a polymerizable monomer, the polymerizable monomer includes a hydroxyalkyl (meth)acrylate, acrylonitrile and a (meth)acrylic ester.

5. The adhesive according to claim 1, wherein the isocyanate compound includes at least one compound selected from aliphatic and alicyclic isocyanates.

6. The adhesive according to claim 1, further comprising other components selected from catalyst, tackifier resin, pigment, plasticizer, flame retardant, wax, silane compound and combinations thereof.

7. A laminated sheet comprising adjacent films bonded together by cured reaction products of the adhesive according to claim 1.

8. An article comprising a laminated sheet including adjacent films bonded together by cured reaction products of the adhesive according to claim 1.

9. A solar battery back sheet comprising the adhesive according to claim 1.

10. A solar battery module comprising the adhesive according to claim 1.
